(19) United States
(12) Patent Application Publication
(10) Pub. No.: US 2014/0293706 A1
(43) Pub. Date: Oct. 2, 2014

(54) SEMICONDUCTOR MEMORY DEVICE, MEMORY MANAGEMENT METHOD, AND ELECTRONIC APPARATUS

(71) Applicant: Sony Corporation, Tokyo (JP)

(72) Inventor: Yohei Yamaguchi, Tokyo (JP)

(73) Assignee: Sony Corporation, Tokyo (JP)

(21) Appl. No.: 14/205,445

(22) Filed: Mar. 12, 2014

(30) Foreign Application Priority Data
Mar. 29, 2013 (JP) 2013-071909

(51) Int. Cl. G11C 16/32

(52) U.S. Cl. CPC G11C 16/32
USPC 365/185.18

(57) ABSTRACT

There is provided a semiconductor memory device including a bit line configured to write data, and a time measurement unit configured to measure a write time of the bit line.

### CROSS REFERENCE TO RELATED APPLICATIONS

This application claims the benefit of Japanese Priority Patent Application JP 2013-071909 filed Mar. 23, 2013, the entire contents of which are incorporated herein by reference.

### BACKGROUND

The present disclosure relates to semiconductor memory devices, memory management methods, and electronic apparatuses.

Semiconductor memory devices in which stored data can be rewritten have in recent years been widely used as storage devices. Such semiconductor memory devices are structurally limited to a finite number of times the semiconductor memory device can be written (hereinafter also referred to as “the number of write cycles”). For example, when a data write operation continues to be performed in a portion of the storage area of a semiconductor memory device, then if the number of write cycles in the storage area portion exceeds the limit, a write error occurs in the storage area portion, which therefore is unusable.

When a write error occurs in a portion of the storage area, which therefore is unusable as described above, the semiconductor memory device may be unusable even if the other portion of the storage area is usable,. Therefore, techniques of controlling the semiconductor memory device so that the number of write cycles to a particular portion of the storage area does not exceed the limit have been studied in order to improve the reliability of the semiconductor memory device.

For example, JP 2011-198433A describes a semiconductor memory device in which a dummy block is provided in addition to storage blocks which are data erase segments (i.e., data is erased on a storage block basis), and based on a data write time of the dummy block, it is determined whether or not a storage block can be rewritten.

### SUMMARY

However, in the technique described in JP 2011-198433A supra, information about the storage area can only be obtained on a storage block (erase segment) basis, and therefore, the storage area of the semiconductor memory device can be managed, only in storage blocks. Therefore, there has been a demand for a technique of managing the storage area of the semiconductor memory device in segments which are smaller than the storage block.

Therefore, the present disclosure proposes a novel and improved semiconductor memory device, memory management method, and electronic apparatus in which the storage area of a semiconductor memory device can be efficiently managed in segments which are smaller than the storage block.

According to an embodiment of the present disclosure, there is provided a semiconductor memory device including a bit line configured to write data, and a time measurement unit configured to measure a write time of the bit line.

According to an embodiment of the present disclosure, there is provided a memory management method including measuring a write time of a bit line configured to write data.

According to an embodiment of the present disclosure, there is provided an electronic apparatus including a semiconductor memory device including a bit line configured to write data, and a time measurement unit configured to measure a write time of a bit line.

As described above, according to the embodiments of the present disclosure, the storage area of a semiconductor memory device can be efficiently managed in segments which are smaller than the storage block.

### BRIEF DESCRIPTION OF THE DRAWINGS

FIG. 1 is an external view showing a specific example of an electronic apparatus including a semiconductor memory device according to an embodiment of the present disclosure;

FIG. 2 is a block diagram showing an internal configuration of a television set including the semiconductor memory device of the embodiment;

FIG. 3 is a block diagram showing an internal configuration of the semiconductor memory device of the embodiment;

FIG. 4 is a diagram showing an equivalent circuit of a semiconductor circuit included in a data storage unit according to the embodiment;

FIG. 5 is a flowchart diagram for describing an operation of the semiconductor memory device of the embodiment;

FIG. 6 is a diagram for describing a data arrangement of the data storage unit;

FIG. 7 is a diagram for describing specific example mapping information set by a line control unit;

FIG. 8 is a diagram for describing a relationship between the write history and the number of write cycles of a semiconductor memory device according to a comparative example;

FIG. 9 is a diagram for describing the write history and the number of write cycles of the semiconductor memory device of an embodiment of the present disclosure;

FIG. 10 is a circuit diagram for describing a first variation of the semiconductor memory device of an embodiment of the present disclosure; and

FIG. 11 is a circuit diagram for describing a second variation of the semiconductor memory device of an embodiment of the present disclosure.

### DETAILED DESCRIPTION OF THE EMBODIMENT(S)

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

The description will be given in the following order.

1. An electronic apparatus including a semiconductor memory device according to an embodiment of the present disclosure

1.1. An example external appearance of the electronic apparatus

1.2. An internal configuration of the electronic apparatus

2. A semiconductor memory device according to an embodiment of the present disclosure

2.1. An internal configuration of the semiconductor memory device

2.2. An operation of the semiconductor memory device

2.2.1. An operation of a data storage unit included in the semiconductor memory device

2.2.2. An operation of the semiconductor memory device

2.3. An example advantage of the semiconductor memory device

2.4. Variations

3. Conclusion

### 1. An Electronic Apparatus Including a Semiconductor Memory Device According to an Embodiment of the Present Disclosure

[1.1. An Example External Appearance of the Electronic Apparatus]

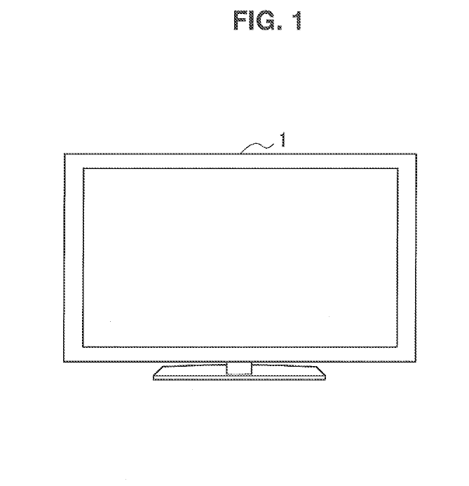

Firstly, a schematic configuration of an electronic apparatus including a semiconductor memory device according to an embodiment of the present disclosure will be described with reference to FIG. 1. FIG. 1 is an external view showing a specific example of an electronic apparatus including a semiconductor memory device according to an embodiment of the present disclosure.

As shown in FIG. 1, an electronic apparatus including a semiconductor memory device according to an embodiment of the present disclosure is, for example, a television set 1 including a semiconductor memory device in which stored data can be rewritten, etc.

The television set 1 will now be described as an electronic apparatus including a semiconductor memory device according to an embodiment of the present disclosure. The subject matter of the present disclosure is not limited to this. An electronic apparatus including a semiconductor memory device according to an embodiment of the present disclosure may be, for example, a personal computer, a solid state drive (SSD) device, or the like.

[1.2. An Internal Configuration of the Electronic Apparatus]

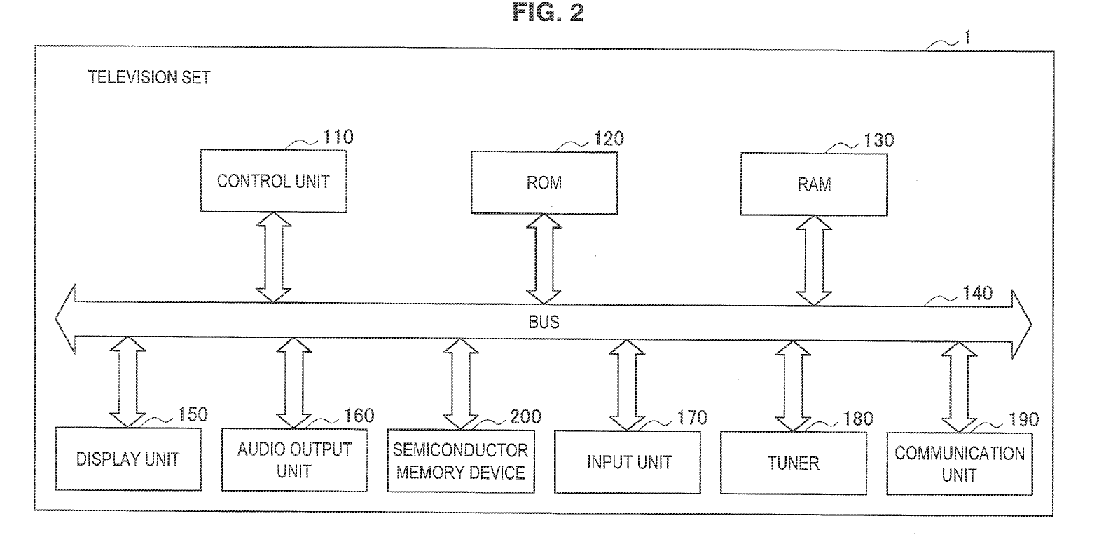

Next, an internal configuration of the television set 1 including a semiconductor memory device according to an embodiment of the present disclosure will be described with reference to FIG. 2. FIG. 2 is a block diagram showing the internal configuration of the television set 1 including a semiconductor memory device according to an embodiment of the present disclosure.

As shown in FIG. 2, the television set 1 including a semiconductor memory device according to an embodiment of the present disclosure includes a control unit 110, a read only memory (ROM) 120, a random access memory (RAM) 130, a bus 140, a display unit 150, an audio output unit 160, an input unit 170, a tuner 180, a communication unit 190, and a semiconductor memory device 200.

The control unit 110, which has a computational function, controls the overall operation of the television set 1 in accordance with various programs. The control unit 110 may be, for example, a central processing unit (CPU), etc.

The ROM 120 is a storage device in which programs, computational parameters, etc. which are used by the control unit 110 are previously written and stored.

The RAM 130 is a storage device in which stored data can be rewritten and which can preserve the data only when power is supplied to the device. The RAM 130 temporarily stores, for example, programs used in execution of the control unit 110, parameters which are changed as appropriate during the execution, etc.

The bus 140 connects the control unit 110, the ROM 120, and the RAM 130 together. The bus 140 also connects the control unit 110, the ROM 120, and the RAM 130 with the display unit 150, the audio output unit 160, the input unit 170, the tuner 180, the communication unit 190, and the semiconductor memory device 200.

The display unit 150 displays video data received by the tuner 180, video data input from the input unit 170, video data received by the communication unit 190, etc. The display unit 150 may be, for example, a liquid crystal display (LCD) device, an organic light emitting diode (OLED) device, and a cathode ray tube (CRT) display device, etc.

As with the display unit 150, the audio output unit 160 converts audio data received by the tuner 180, audio data input from the input unit 170, audio data received by the communication unit 190, etc. into sound, and outputs the sound. The audio output unit 160 may be, for example, an audio output device, such as a loudspeaker, headphones, etc.

The input unit 170 is an interface which allows external data to be input to the television set 1. The input unit 170 may be, for example, a connection interface including a connection port for connecting an external connection apparatus to the television set 1, such as an RCA terminal, an optical audio terminal, a high-definition multimedia interface (HDMI) (registered trademark) terminal, etc.

The tuner 180 is a device which receives and converts a broadcast signal etc. into video and audio data etc. The tuner 180 also outputs the video data and the audio data to the display unit 150 and the audio output unit 160, respectively. Here, the tuner 180 may also receive data for an electronic program guide, etc.

The communication unit 190 is, for example, a communication interface including a communication device etc. for connecting to the Internet. The communication unit 190 may be a wired local area network (LAN)-supporting or wireless LAN-supporting communication device or a wire communication device for performing wired communication.

The semiconductor memory device 200 is a storage device in which stored data can be rewritten and which can preserve the data even when power is not supplied to the device. The semiconductor memory device 200 may store, for example, data for an electronic program guide etc. received by the tuner 180, or video data received by the tuner 180.

As described above, the semiconductor memory device 200 of the embodiment of the present disclosure is included in various electronic apparatuses to store various kinds of data. A specific configuration of the semiconductor memory device 200 will now be described.

### 2. A Semiconductor Memory Device According to an Embodiment of the Present Disclosure

[2.1. An Internal Configuration of the Semiconductor Memory Device

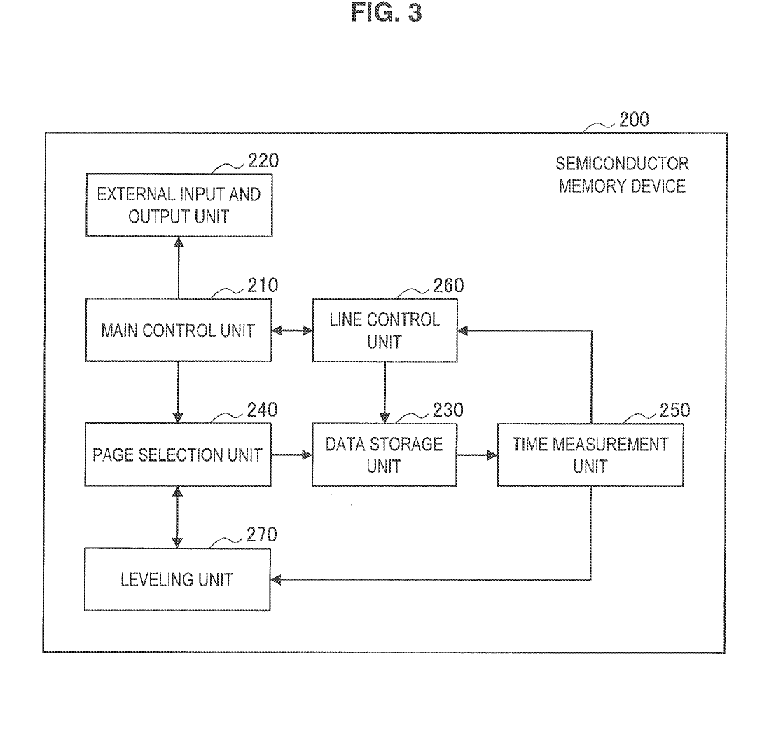

Next, an internal configuration of the semiconductor memory device 200 of the embodiment of the present disclosure will be described with reference to FIG. 3. FIG. 3 is a block diagram showing the internal configuration of the semiconductor memory device 200 of the embodiment of the present disclosure.

As shown in FIG. 3, the semiconductor memory device 200 of the embodiment of the present disclosure includes a main control unit 210, an external input and output unit 220, a data storage unit 230, a page selection unit 240, a time measurement unit 250, a line control unit 260, and a leveling unit 270.

The main control unit 210 is a computational circuit which controls the overall operation of the semiconductor memory device 200 to perform write, read, and erase operations etc. on the data storage unit 230. Specifically, the main control unit 210 obtains data from the input unit 170, the tuner 180, the communication unit 190, etc. of the television set 1 via the external input and output unit 220, and writes the data to the data storage unit 230. The main control unit 210 also reads stored data from the data storage unit 230, and outputs the stored data via the external input and output unit 220.

The external input and output unit 220 is an interface which performs data input and output between the semiconductor memory device 200 and an external device. The external input and output unit 220 may be, for example, a connection interface including a universal serial bus (USB) port, an IEEE1394 port, a small computer system interface (SCSI), a serial advanced technology attachment (SATA) port, etc.

The data storage unit 230 is a semiconductor storage element which stores data which is stored in the semiconductor memory device 200. Specifically, the data storage unit 230 includes a plurality of storage blocks. Each storage block includes a plurality of pages (e.g., 64 pages etc.). Each page includes a plurality of memory cells (e.g., 16,000 memory cells etc.). The data storage unit 230 is written and read in pages and erased in storage blocks.

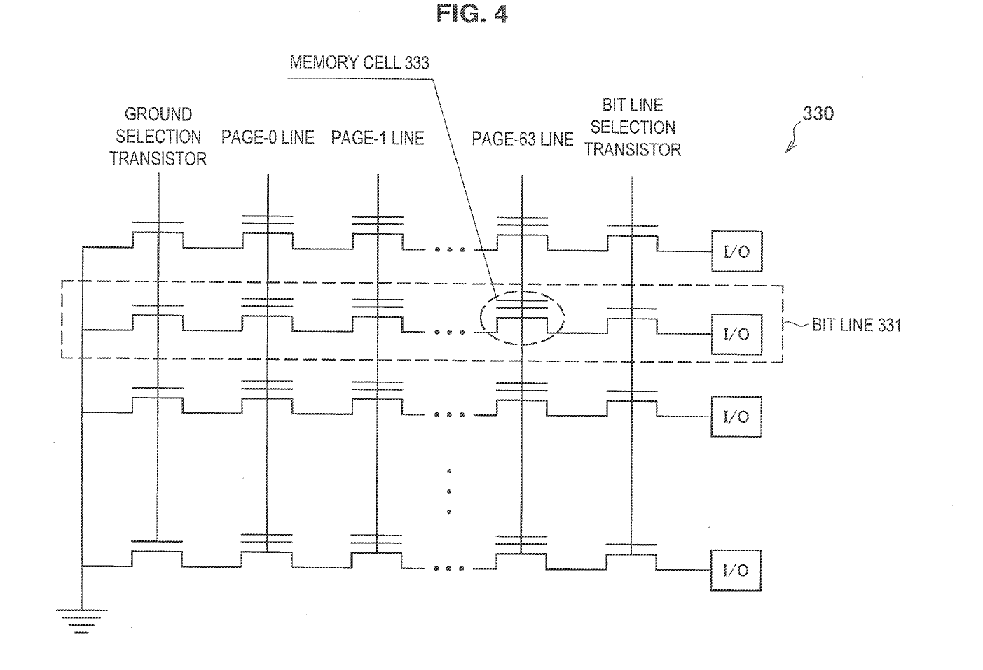

A specific circuit configuration of the data storage unit 230 will now be described with reference to FIG. 4. FIG. 4 is a diagram for describing a semiconductor circuit 330 included in the data storage unit 230.

The semiconductor circuit 330 of FIG. 4 included in the data storage unit 230 includes a plurality of interconnects which are called “page lines,” i.e., “page-0 line” to “page-63 line,” and a plurality of interconnects intersecting the page lines which are called “bit lines.” A storage element including a semiconductor element is provided at each of intersections between the page lines and the bit lines. Ground selection transistors and bit line selection transistors are provided on opposite sides of the page lines. Here, each storage element is the above-described memory cell, and a set of storage elements on each page line corresponds to one page. Note that data write, read, and erase operations of the data storage unit 230 including the semiconductor circuit 330 will be described below.

The page selection unit 240 is a circuit unit which selects a page on which an operation is to be performed by the main control unit 210. Specifically, when the main control unit 210 writes data to the data storage unit 230, the page selection unit 240 selects a page line to which the data is to be written. The page selection unit 240, when instructed by the main control unit 210 to read data, also selects a page line on which the data to be read from the data storage unit 230 is stored.

The time measurement unit 250 is a circuit unit which, when data is written to memory cells, measures or calculates the time it takes to write the data (write time) for each bit line. Here, every time a memory cell is written, the memory cell deteriorates, so that the time it takes to write the memory cell becomes shorter. Therefore, the semiconductor memory device 200 of the embodiment of the present disclosure measures the memory cell write time of each bit line, and therefore, can estimate the degree of deterioration and the number of write cycles of each bit line. Because the semiconductor memory device 200 of the embodiment of the present disclosure can estimate the degree of deterioration and the number of write cycles of each bit line based on the write time, and therefore, can manage memory cells on a bit line basis.

Note that the time measurement unit 250 may measure the time it takes to write each memory cell on a bit line, and set the write time of the bit line to a shortest one of the write times of the memory cells. Alternatively, the time measurement unit 250 may measure the time it takes to write data to a bit line based on a voltage change which occurs when data is written to the bit line, and set the write time of the bit line to that time. Note that the write time measurement on an individual memory cell basis is more preferable because a more accurate bit line write time can be obtained.

The line control unit 260 is a circuit unit which controls bit lines which are used to write data, based on the write times which have been measured on a bit line basis by the time measurement unit 250. Specifically, in the semiconductor memory device 200, the data storage unit 230 includes main bit lines and spare bit lines, and the line control unit 260 switches a bit line which is used from a main bit line to a spare bit line, depending on the write time of the bit line.

More specifically, the line control unit 260 normally performs a control so that main bit lines are used to write data. However, when a bit line for which the write time is shorter than a threshold is detected, the line control unit 260 determines that the bit line is unusable, and replaces the bit line with a spare bit line. The line control unit 260 also causes the data storage unit 230 to store mapping information indicating which of the main bit lines is unusable and which of the spare bit lines has replaced that bit line. With this configuration, for example, the line control unit 260 replaces a main bit line on which write operation has been concentrated due to characteristics of data and which therefore has become unusable with a spare bit line, whereby the situation that the entire storage block becomes unusable is prevented.

Also, for example, the line control unit 260 may determine whether or not a bit line is unusable, not only based on the write time of that bit line, but also based on the write time of a bit line in another storage block at the same position where that bit line is located. When a write operation is concentrated on a particular bit line due to characteristics of data, it is highly likely that a write operation is also concentrated on bit lines in other storage blocks at the same position where the particular bit line is located. Therefore, by referencing the write times of a plurality of bit lines at the same position, it can be more accurately determined whether or not a bit line is unusable.

Moreover, for example, the line control unit 260 may control bit lines to which data is to be written to level the write times of the individual bit lines based on those which have been measured by the time measurement unit 250. Specifically, the line control unit 260, when the write time of a bit line to which data is to be written is short, may swap that bit line for another bit line having a longer write time and write data to the bit line having a longer write time, before the write time of that bit line becomes shorter than the threshold.

The leveling unit 270 is a circuit unit which performs an algorithm of leveling the numbers of write cycles of individual memory cells in the data storage unit 230 (such an algorithm is also called “wear leveling”). Specifically, the leveling unit 270 measures the number of write cycles of each page, and performs a control so that data is written to a page having a smaller number of write cycles in order to level the numbers of write cycles. The leveling unit 270 also causes the data storage unit 230 to store conversion information indicating which of the pages was used to write data during wear leveling.

Alternatively, the leveling unit 270 may estimate the numbers of write cycles of the individual bit lines based on the write times of the individual bit lines measured by the time measurement unit 250, and perform wear leveling based on the estimated numbers of write cycles. Still alternatively, the leveling unit 270 may perform wear leveling based on the numbers of write cycles of the individual bit lines which have been estimated based on the write times of the individual bit lines and the numbers of write cycles of the individual pages which have been measured.

The internal configuration of the semiconductor memory device 200 of the embodiment of the present disclosure has so far been specifically described. In the semiconductor memory device 200 of the embodiment of the present disclosure having the above-described configuration, the write time is measured for each bit line, and therefore, the data storage unit 230 of the semiconductor memory device 200 can be managed in bit lines which are smaller than the storage block.

In the semiconductor memory device 200 of the embodiment of the present disclosure, the write time is measured for each bit line, and therefore, the number of write cycles can be estimated for each bit line, for which it is difficult to measure the number of write cycles because data is not written on a bit line basis.

Here, the semiconductor memory device 200 of the embodiment of the present disclosure measures the write times of bit lines and determines the degrees of deterioration of the bit lines every time a data write operation is performed. Therefore, with this configuration, the situation that the storage area which can be used by the user is reduced by storing the number of write cycles etc., the situation that the power is accidentally turned off before the number of write cycles etc. is stored and therefore the number of write cycles is lost or incorrect, etc. can be avoided. However, needless to say, in order to determine whether or not a bit line to which data is to be written is usable prior to a write operation, the time measurement unit 250 may cause the data storage unit 230 to store the previous write time of each bit line.

Although, in the above embodiment, the write times of the individual bit lines measured by the time measurement unit 250 are used to control and determine a bit line to which data is to be written, the present disclosure is not limited to this. Alternatively, for example, the semiconductor memory device 200 may output the write times of the individual bit lines from the external input and output unit 220, and the write times of the individual bit lines may be displayed on the display unit 150 as information about the life expectancy of the semiconductor memory device 200. Still alternatively, for example, the semiconductor memory device 200 may output the write times of the individual bit lines from the external input and output unit 220, and the write times of the individual bit lines may be, for example, used to inspect the semiconductor memory device 200 to find out a defect or failure.

[2.2. An Operation of the Semiconductor Memory Device]

(2.2.1. An Operation of a Data Storage Unit Included in the Semiconductor Memory Device)

An operation of the semiconductor memory device of the embodiment of the present disclosure will now be described with reference to FIGS. 4-7. Firstly, an operation of the data storage unit 230 included in the semiconductor memory device of the embodiment of the present disclosure will be described with reference to FIG. 4. Specifically, a data write operation to the data storage unit 230, a data read operation from the data storage unit 230, and a data erase operation from the data storage unit 230 will be described.

Although, in the description that follows, each memory cell stores 1-bit information, the subject matter of the present disclosure is not limited to this. For example, each memory cell may store 2-bit or multi-bit information.

Firstly, a data write operation to the data storage unit 230 will be described. When a write operation is performed on a memory cell 333 shown in FIG. 4, a write voltage (Vpgm) is applied to the control gate of the memory cell 333 which is to be written. A voltage (Vpass, where Vpgm>Vpass) which turns on a cell transistor is applied to the control gates of the other memory cells on a bit line 331 which are not to be written. A power supply voltage (Vdd) is applied to the gate of the bit line selection transistor on the bit line 331, and a ground voltage (0 V) is applied to the gate of the ground selection transistor on the bit line 331.

Here, when the voltage of the bit line 331 is 0 V, the bit line selection transistor is on, and therefore, a high electric field is applied to the memory cell 333 which is to be written, so that electrons are injected into the memory cell 333 (i.e., the memory cell 333 is charged). When the voltage of the bit line 331 is Vdd, the bit line selection transistor is off, a high electric field is not applied to the memory cell 333 which is to be written, so that electrons are not injected into the memory cell 333. Therefore, by changing the voltage of the bit line 331, the presence or absence of electric charge (injected electrons) in the memory cell 333 can be controlled, and 1-bit information “0” or “1” indicating the presence or absence of electric charge (injected electrons) can be stored. Note that a data write operation is performed on a page line basis, and all memory cells on the same page line are simultaneously written. Write operations to the page lines are performed in parallel.

Next, a data read operation from the data storage unit 230 will be described. When information is read from the memory cell 333 of FIG. 4, a voltage of 0 V is applied to the control gate of the memory cell 333 which is to be read. A voltage (e.g., a voltage equal to Vpass) which turns on the cell transistor is applied to the control gates of memory cells which are not to be read and the gates of the bit line selection transistor and the ground selection transistor. Here, when electrons have been injected into the memory cell 333 (i.e., the memory cell 333 is charged), a current does not flow. On the other hand, when electrons have not been injected into the memory cell 333 (i.e., the memory cell 333 is not charged), a current flows. By detecting the current, information stored in the memory cell 333 can be read. Note that, as with a data write operation, a data read operation is performed in a page line basis, and all memory cells on the same page line are simultaneously read. Data read operations from the page lines are performed in parallel.

Next, a data erase operation from the data storage unit 230 will be described. A data erase operation is performed on a storage block basis. A voltage of 0 V is applied to the control gates of memory cells in a storage block which is to be erased, and the control gates of memory cells in a storage block which is not to be erased are opened. The gates of each bit line selection transistor and each ground selection transistor are opened. An erase voltage (e.g., 20 V etc.) is applied to a P-type semiconductor layer (well) of a semiconductor substrate in which the semiconductor circuit of the data storage unit 230 is formed. Here, a high electric field is applied to the memory cells to which a voltage of 0 V is applied, and therefore, electrons are removed from the memory cells, whereby data is erased. Because a high electric field is not applied to the opened memory cells, electrons are not removed from the opened memory cells, and therefore, data is not erased from the opened memory cells.

The operation of the data storage unit 230 in the semiconductor memory device 200 of the embodiment of the present disclosure has so far been described. As described above, the semiconductor circuit of the data storage unit 230 performs a data write operation and a data erase operation by injecting and removing electrons into and from memory cells. Therefore, if a data write operation is repeatedly performed on the data storage unit 230, memory cells deteriorate due to the injection and removal of electrons and eventually fail to normally store data. Therefore, an upper limit is put on the number of data write cycles of each memory cell, and the memory cell is managed so that the number of write cycles does not exceed the upper limit.

(2.2.2. An Operation of the Semiconductor Memory Device)

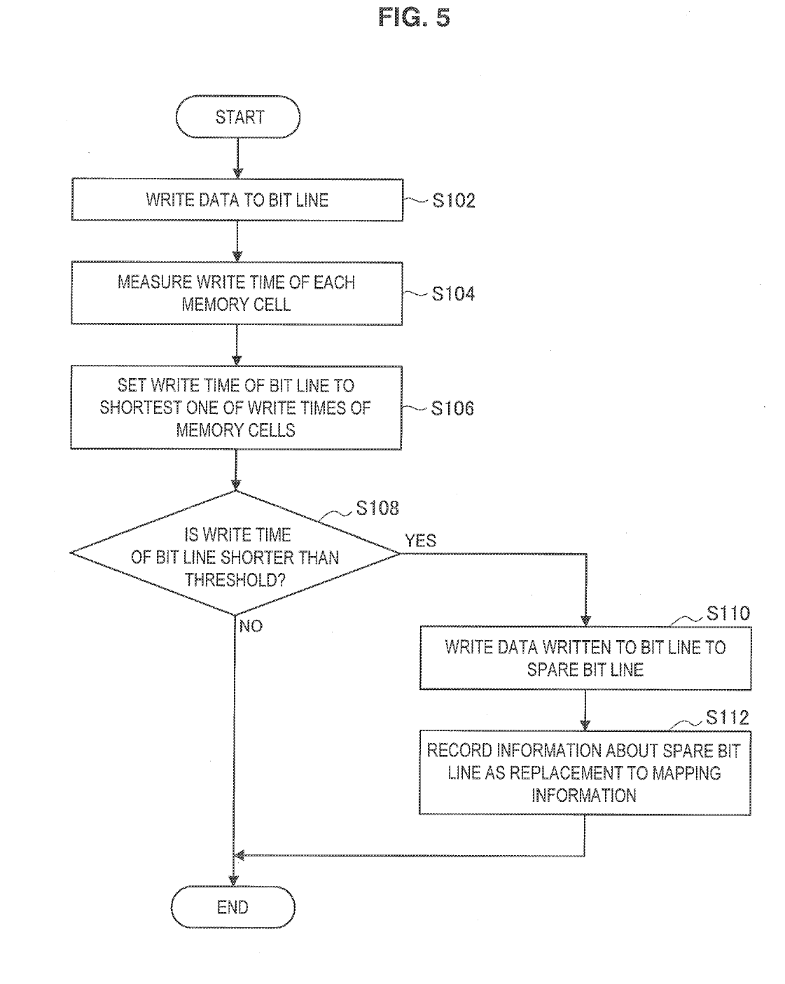

Next, an operation of the semiconductor memory device 200 of the embodiment of the present disclosure will be described with reference to FIGS. 5-7. Here, FIG. 5 is a flowchart diagram for describing the operation of the semiconductor memory device 200 of the embodiment of the present disclosure.

As shown in FIG. 5, initially, the main control unit 210 of the semiconductor memory device 200 of the embodiment of the present disclosure transmits, to the page selection unit 240 and the line control unit 260, an instruction to write data to a bit line (S102). Next, the main control unit 210 writes data to a main bit line selected by the page selection unit 240 and the line control unit 260 (S104). The time measurement unit 250 measures the data write time of each memory cell on the main bit line (S104). The time measurement unit 250 also determines which of the data write times of the memory cells is shortest and defines the shortest write time as the write time of the main bit line (S106).

Here, the line control unit 260 determines whether or not the write time measured by the time measurement unit 250 is shorter than the threshold (S108). If the write time is not shorter than the threshold (S108/No), the line control unit 260 determines that the main bit line is usable, and the main control unit 210 ends the data write operation.

If the write time is shorter than the threshold (S108/Yes), the line control unit 260 determines that the main bit line is unusable. If it is determined that the main bit line is unusable, the line control unit 260 designates a spare bit line as a replacement for the main bit line, and instructs the main control unit 210 to write data written to the main bit line to the spare bit line (S110). When the main control unit 210 ends the data write operation to the spare bit line, the line control unit 260 records, as mapping information, information about a correspondence relationship between the main bit line determined as being unusable and the spare bit line designated as a replacement (S112).

Note that, in the foregoing description, for the sake of simplicity, the operation of the semiconductor memory device 200 has been described, with attention given to one main bit line. In actual practice, however, in the semiconductor memory device 200, a write operation is performed on a plurality of bit lines in parallel, and therefore, an operation similar to the above operation is performed on a plurality of bit lines in parallel.

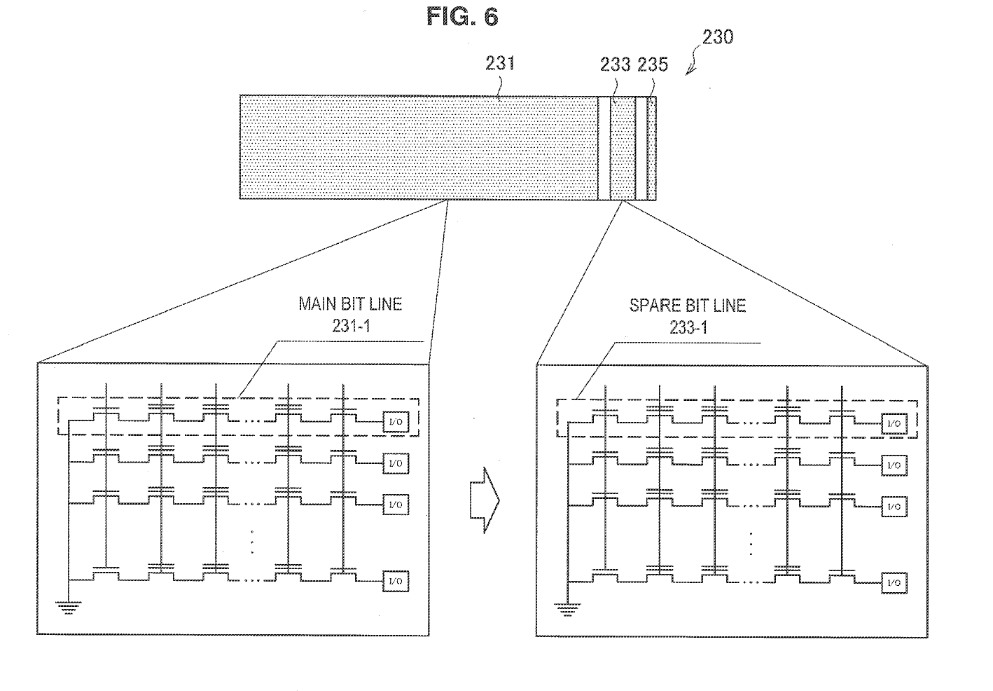

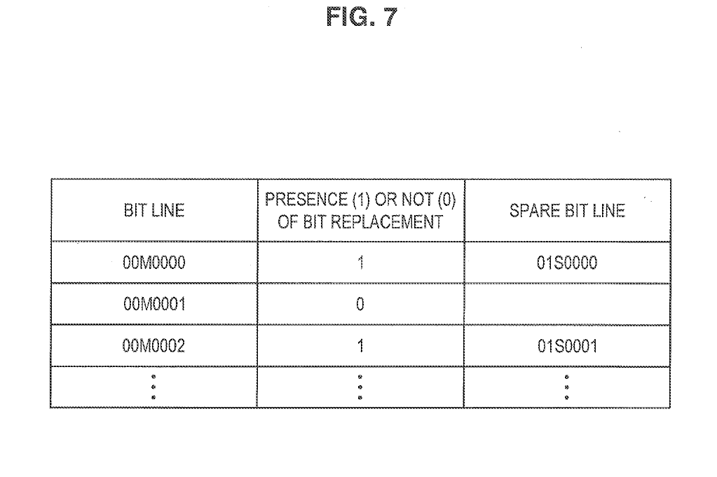

Next, the above operation of the semiconductor memory device 200 will be more specifically described with reference to FIGS. 6 and 7. Here, FIG. 6 is a diagram for describing a data arrangement of the data storage unit 230. FIG. 7 is a diagram for describing a specific example of the mapping information set by the line control unit 260.

As shown in FIG. 6, the data storage unit 230 included in the semiconductor memory device 200 of the embodiment of the present disclosure includes a main bit line area 231, a spare bit line area 233, and a mapping information storage area 235.

The main bit line area 231 is a storage area on which data write and erase operations are mainly performed. The spare bit line area 233 is a storage area which is used as a replacement when the line control unit 260 determines that a portion of the bit lines included in the main bit line area 231 is unusable. The mapping information storage area 235 is a storage area which stores a correspondence relationship information between a main bit line determined as being unusable and a spare bit line when a bit line is switched from the main bit line area 231 to the spare bit line area 233.

For example, an example case where data is written to a main bit line 231-1 in the main bit line area 231 will be described. Initially, when the main control unit 210 writes data to the main bit line 231-1, the time measurement unit 250 measures the data write time of the main bit line 231-1. If the measured write time is not shorter than the threshold, it is determined that the main bit line 231-1 is usable, and the data write operation is ended.

If the measured write time is shorter than the threshold, the line control unit 260 determines that the main bit line 231-1 is unusable. In this case, the line control unit 260 instructs the main control unit 210 to write the same data to a spare bit line 233-1 of the spare bit line area 233, and the data is written to the spare bit line 233-1. The line control unit 260 also records, into the mapping information storage area 235, mapping information indicating that the main bit line 231-1 is unusable and has been replaced with the spare bit line 233-1.

Here, a specific example of the mapping information stored in the mapping information storage area 235 is shown in FIG. 7. For example, as shown in FIG. 7, the mapping information stored in the mapping information storage area 235 contains fields “bit line,” “presence or not of bit replacement,” and “spare bit line.”

For example, for a bit line “00M0000,” the “presence or not of bit replacement” field has a value of “1” which indicates the presence of bit replacement, and therefore, it has been determined that the bit line is unusable, and it is indicated that the bit line has been replaced with a spare bit line “01S0000.” For a bit line “00M0001,” the “presence or not of bit replacement” field has a value of “0” which indicates the absence of bit replacement. Therefore, it has been determined that the bit line “00M0001” is usable, and the “spare bit line” field which indicates a replacement is empty. For a bit line “00M0002,” the “presence or not of bit replacement” field has a value of “1” which indicates the presence of bit replacement, and therefore, it has been determined that the bit line is unusable, and it is indicated that the bit line has been replaced with a spare bit line “01S0001.”

The operation of the semiconductor memory device 200 of the embodiment of the present disclosure has so far been described. Although, in the above embodiment, a main bit line is replaced with a spare bit line on an individual bit line basis, the subject matter of the present disclosure is not limited to this. For example, bit lines may be divided into groups each including a plurality of bit lines, and if it is determined that a predetermined number of bit lines are unusable in a group, all bit lines in the group may be switched from main bit lines to spare bit lines. In this case, replacement is performed on a bit line group basis, and therefore, the capacity of the mapping information storage area 235 can be reduced. Therefore, the storage area can be more efficiently used by the user.

[2.3. An Example Advantage of the Semiconductor Memory Device]

An example advantage of the semiconductor memory device 200 of the embodiment of the present disclosure will be specifically described. In the description that follows, the state in which electrons have been injected into a memory cell (i.e., the memory cell is charged) represents information “0,” and the state in which electrons have not been injected into a memory cell (i.e., the memory cell is not charged) represents information “1.”

Here, as described in the section (2.2.2. An operation of the semiconductor memory device), the semiconductor memory device stores information based on whether or not electrons have been injected into a memory cell (i.e., the memory cell is charged). In the semiconductor memory device, when data is written to a memory cell of a storage block in which other data was previously stored, all memory cells of the storage block are returned to the non-charged state, and thereafter, electrons are injected into that memory cell based on write data.

For example, when a memory cell is rewritten from “1” to “1,” neither of the removal and injection of electrons occurs. When a memory cell is rewritten from “1” to “0,” only the injection of electrons occurs. When a memory cell is rewritten from “0” to “1,” only the removal of electrons occurs. When a memory cell is rewritten from “0” to “0,” both the removal and injection of electrons occur.

Therefore, in the above example, when a memory cell is written to “0,” the injection or removal of electrons occurs in the memory cell, which therefore deteriorates.

On the other hand, when a memory cell continues to be written to “1,” neither of the removal and injection of electrons occurs, and therefore, the memory cell does not deteriorate.

Therefore, if data containing “0” at a particular bit is written at a high frequency, a memory cell to which data of that bit is written deteriorates faster than memory cells to which data of other bits is written.

In this case, by measuring the data write time, the semiconductor memory device 200 of the embodiment of the present disclosure can find out a bit line which has a memory cell which has deteriorated more than other memory cells. Also, by replacing the bit line having the significantly deteriorated memory cell with a spare bit line, memory cells on the different bit line, which have not significantly deteriorated, can be efficiently used.

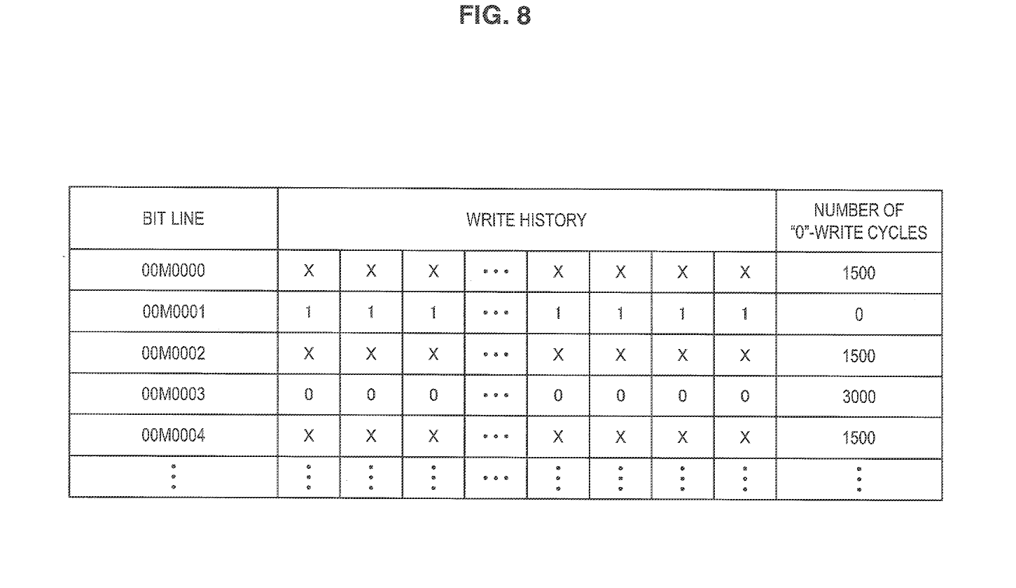

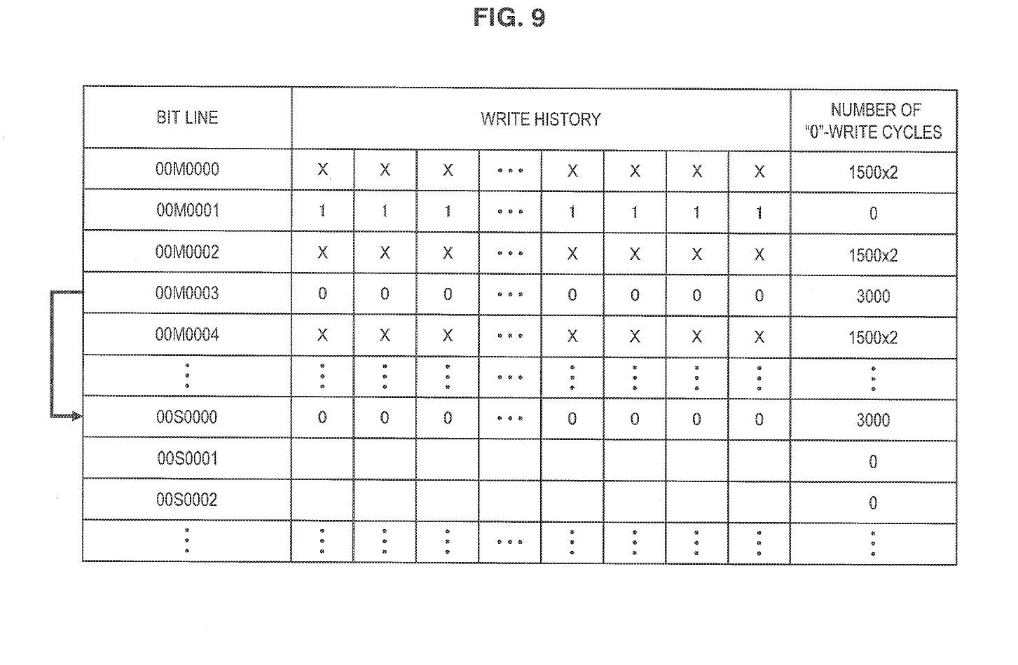

The example advantage of the semiconductor memory device 200 of the embodiment of the present disclosure that memory cells can be efficiently used will now be specifically described with reference to FIGS. 8 and 9.

Here, FIG. 8 is a diagram for describing a relationship between the write history and the number of write cycles of a semiconductor memory device according to a comparative example. FIG. 9 is a diagram for describing the write history and the number of write cycles of the semiconductor memory device 200 of the embodiment of the present disclosure. Note that the semiconductor memory device of the comparative example does not include the time measurement unit 250 or the line control unit 260 of the embodiment of the present disclosure. It is assumed that the numbers of write cycles of these semiconductor memory devices have an upper limit of 3000.

FIGS. 8 and 9 show examples in which data is repeatedly written in which “0” and “1” specifically appear at particular bits. In the data, the second bit invariably has a value of “1,” the fourth bit invariably has a value of “0,” and the other bits take a value of “1” or “0” at a rate of 1:1. Therefore, the write history of a bit line “00M0001” which has a memory cell to which the second bit which invariably has a value of “1” is written, invariably has a value of “1.” The write history of a bit line “00M0003” which has a memory cell to which the fourth bit which invariably has a value of “0” is written, invariably has a value of “0.” The write history of bit lines “00M0000,” “00M0002,” and “00M0004” which take “1” or “0” at a rate of 1:1, is represented by “X.”

In the semiconductor memory device of the comparative example of FIG. 8, when the above data has been written 3000 times, “0” has been written to the bit line “00M0003” 3000 times. Therefore, the bit line “00M0003” causes a write error and therefore is unusable, and an entire storage block including the bit line also is unusable.

However, for example, for the bit line “00M0001,” the number of “0”-write cycles is zero, and therefore, memory cells do not substantially deteriorate. For the bit lines “00M0000,” “00M0002,” and “00M0004,” the number of “0”-write cycles is 1500, which is 50% of 3000, and therefore, has not reached the upper limit of the number of write cycles.

Therefore, in the semiconductor memory device of the comparative example, the presence of a bit line to which “0” is written at a high frequency causes an entire storage block including that bit line to be unusable when the number of write cycles reaches 3000, even if other bit lines are still usable.

On the other hand, in the semiconductor memory device 200 of the embodiment of the present disclosure, as shown in FIG. 9, when the above data has been written 3000 times, “0” has been similarly written to the bit line “00M0003” 3000 times. Here, the time measurement unit 250 and the line control unit 260 determine that the number of write cycles of the bit line “00M0003” has reached the upper limit, and replace the bit line “00M0003” with the spare bit line “01S0000.” Therefore, the above data can be written to the semiconductor memory device 200 another 3000 times.

In this case, for the bit lines “00M0003” and “01S0000,” to which “0” is invariably written, the number of “0”-write cycles is 3000. Moreover, for the bit lines “00M0000,” “00M0002,” and “00M0004,” for which the number of “0”-write cycles is 1500 the comparative example, the number of “0”-write cycles can reach 1500×2=3000. Therefore, the semiconductor memory device 200 of the embodiment of the present disclosure can efficiently manage memory cells to increase the number of write cycles of the entire semiconductor memory device compared to the semiconductor memory device of the comparative example.

[2.4. Variations]

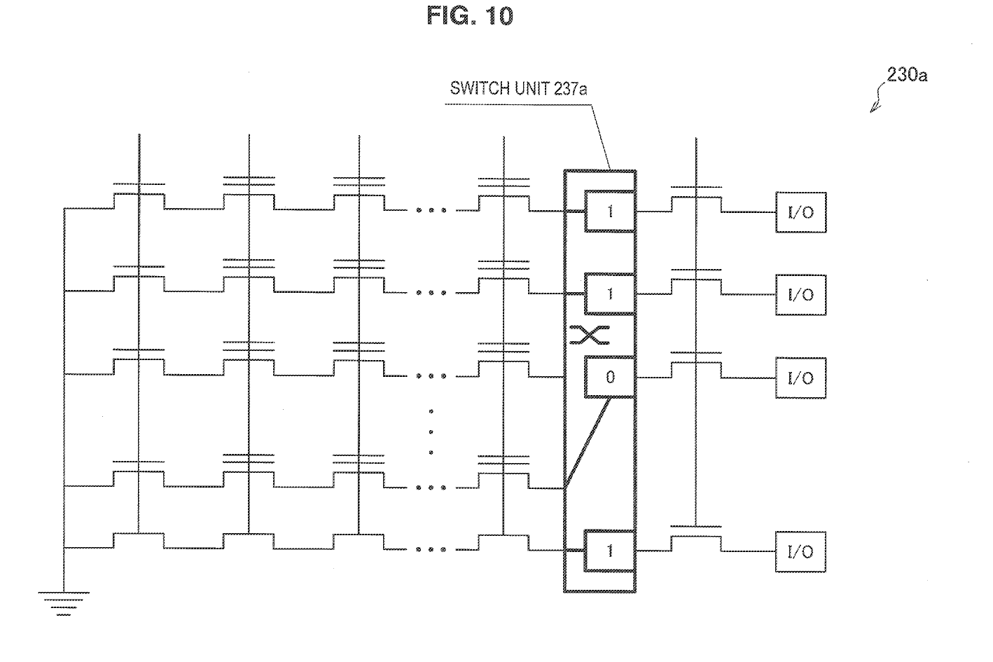

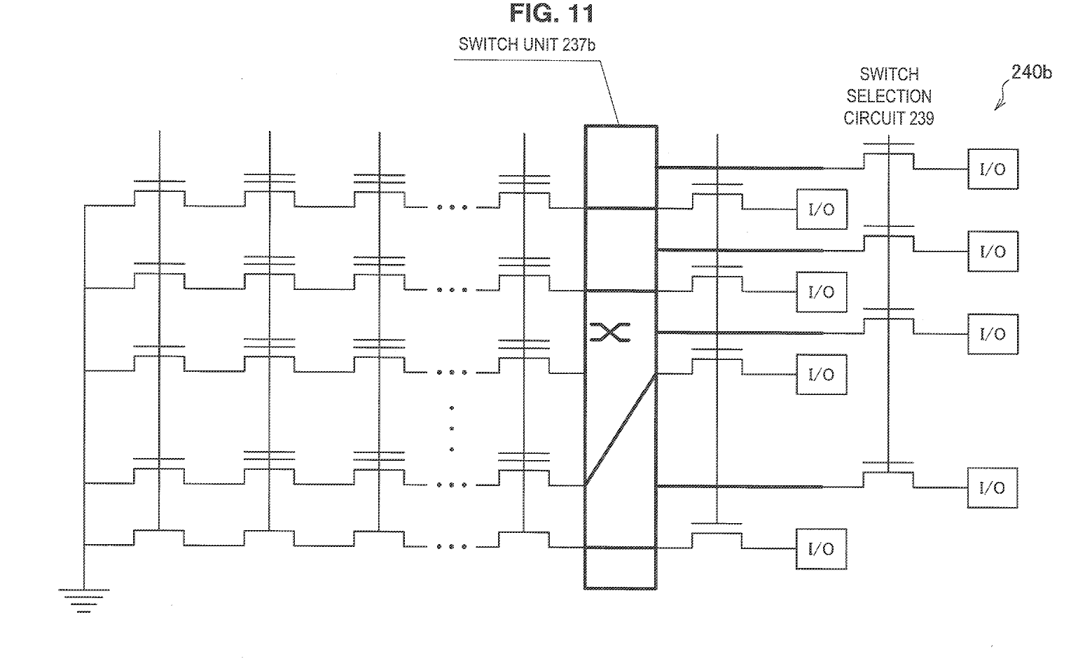

Next, variations of the semiconductor memory device of the embodiment of the present disclosure will be described with reference to FIGS. 10 and 11. Here, FIG. 10 is a circuit diagram for describing a first variation of the semiconductor memory device of the embodiment of the present disclosure. FIG. 11 is a circuit diagram for describing a second variation of the semiconductor memory device of the embodiment of the present disclosure.

Firstly, the first variation of the semiconductor memory device of the embodiment of the present disclosure will be described with reference to FIG. 10. In the first variation of the semiconductor memory device of the embodiment of the present disclosure of FIG. 10, a data storage unit 230a includes a switch unit 237a for replacing a main bit line with a spare bit line.

The switch unit 237a is a circuit unit which can replace an unusable main bit line with a spare bit line in accordance with an instruction from the line control unit 260, and stores information about the replacement. The switch unit 237a maintains the replacement of bit lines, for example, by irreversibly replacing a bit line with another bit line, using a storage element which stores information about the replacement, etc. For example, the switch unit 237a may be a semiconductor switch circuit or a micro electro-mechanical systems (MEMS) switch circuit.

With this configuration, in the first variation, the switch unit 237a maintains the replacement of bit lines, and therefore, it is not necessary for the data storage unit 230a to store mapping information indicating which of spare bit lines has replaced an unusable main bit line. Therefore, in the semiconductor memory device of the first variation, the data storage unit 230a enables the user to use the storage area more efficiently.

Next, a second variation of the semiconductor memory device of the embodiment of the present disclosure will be described with reference to FIG. 11. In the second variation of the semiconductor memory device of the embodiment of the present disclosure of FIG. 11, a data storage unit 230b includes a switch unit 237b and a switch selection circuit 239 which are used to replace a main bit line with a spare bit line. With this configuration, the switch selection circuit 239 controls the switch unit 237b based on mapping information so that a main bit line is replaced with a spare bit line.

The switch unit 237b is a circuit unit which replaces an unusable main bit line with a spare bit line. The switch unit 237b may be, for example, a semiconductor switch circuit or a micro electro-mechanical systems (MEMS) switch circuit. The switch selection circuit 239 is a circuit unit which designates bit lines on which replacement is to be performed by the switch unit 237b, based on the mapping information, during write and read operations. The switch selection circuit 239 may include, for example, a transistor etc.

With this configuration, the second variation of the semiconductor memory device of the embodiment of the present disclosure can be configured using circuits which are more easily available than those of the first variation.

### 3. Conclusion

The electronic apparatus and the semiconductor memory device of the embodiments of the present disclosure have so far been described. In the electronic apparatus and the semiconductor memory device of the embodiments of the present disclosure, the storage area can be managed in bit lines which are smaller than the storage block.

Also, in the electronic apparatus and the semiconductor memory device of the embodiments of the present disclosure, the write time is measured for each bit line, and therefore, the number of write cycles can be estimated for each bit line, for which it is difficult to measure the number of write cycles because data is not written on a bit line basis.

Also, in the electronic apparatus and the semiconductor memory device of the embodiments of the present disclosure, the data write time is measured, and therefore, a bit line can be found out in which one memory cell has deteriorated more than another memory cell. Moreover, a bit line having a memory cell which has significantly deteriorated is replaced with a spare bit line, and therefore, other memory cells which have not significantly deteriorated can be efficiently used.

It should be understood by those skilled in the art that various modifications, combinations, sub-combinations and alterations may occur depending on design requirements and other factors insofar as they are within the scope of the appended claims or the equivalents thereof.

For example, although, in the above embodiments, the time measurement unit 250 is included in the semiconductor memory device 200, the present disclosure is not limited to this. Alternatively, for example, in the electronic apparatus (e.g., the television set 1) of the embodiment of the present disclosure, the semiconductor memory device 200 may not include the time measurement unit 250, and the electronic apparatus (e.g., the television set 1) may include the time measurement unit 250.

Additionally, the present technology may also be configured as below.
(1) A semiconductor memory device including:

a bit line configured to write data; and

a time measurement unit configured to measure a write time of the bit line.
(2) The semiconductor memory device according to (1), wherein the time measurement unit sets the write time of the bit line to a shortest time among the write times of memory cells on the bit line.
(3) The semiconductor memory device according to (1) or (2), further including:

a line control unit configured to control the bit line to be used, based on the write time.
(4) The semiconductor memory device according to (3), wherein

the bit line includes a main bit line and a spare bit line, and

the line control unit switches the bit line to be used, from the main bit line to the spare bit line, based on the write time.
(5) The semiconductor memory device according to (4), wherein

when the write time of the bit line is shorter than a threshold, the line control unit switches the bit line to be used, from the main bit line to the spare bit line.
(6) The semiconductor memory device according to (4) or (5), wherein the line control unit switches a bit line to be used in a unit of a bit line group including a plurality of bit lines, from the main bit line to the spare bit line.
(7) The semiconductor memory device according to any one of (4) to (6), wherein the line control unit switches the bit line to be used, from the main bit line to the spare bit line, based on mapping information indicating the spare bit line that is a replacement to which the bit line to be used is switched.
(8) The semiconductor memory device according to any one of (4) to (6), further including:

a switch unit configured to switch the bit line to be used, from the main bit line to the spare bit line, wherein

the line control unit instructs the switch unit to switch the bit line.
(9) The semiconductor memory device according to any one of (1) to (7), further including:

a leveling unit configured to perform wear leveling in a unit of a page.
(10) The semiconductor memory device according to (9), wherein the leveling unit estimates a number of write cycles of the bit line based on the write time, and performs wear leveling based on the number of write cycles.
(11) The semiconductor memory device according to any one of (1) to (10), further including:

an external output unit configured to externally output the write time of the bit line.
(12) A memory management method including:

measuring a write time of a bit line configured to write data.
(13) An electronic apparatus including:

a semiconductor memory device including a bit line configured to write data; and

a time measurement unit configured to measure a write time of a bit line.

What is claimed is:

1. A semiconductor memory device comprising:
a bit line configured to write data; and
a time measurement unit configured to measure a write time of the bit line.

2. The semiconductor memory device according to claim 1, wherein
the time measurement unit sets the write time of the bit line to a shortest time among the write times of memory cells on the bit line.

3. The semiconductor memory device according to claim 1, further comprising:
a line control unit configured to control the bit line to be used, based on the write time.

4. The semiconductor memory device according to claim 3, wherein
the bit line includes a main bit line and a spare bit line, and
the line control unit switches the bit line to be used, from the main bit line to the spare bit line, based on the write time.

5. The semiconductor memory device according to claim 4, wherein
when the write time of the bit line is shorter than a threshold, the line control unit switches the bit line to be used, from the main bit line to the spare bit line.

6. The semiconductor memory device according to claim 4, wherein
the line control unit switches a bit line to be used in a unit of a bit line group including a plurality of bit lines, from the main bit line to the spare bit line.

7. The semiconductor memory device according to claim 4, wherein
the line control unit switches the bit line to be used, from the main bit line to the spare bit line, based on mapping information indicating the spare bit line that is a replacement to which the bit line to be used is switched.

8. The semiconductor memory device according to claim 4, further comprising:
a switch unit configured to switch the bit line to be used, from the main bit line to the spare bit line, wherein
the line control unit instructs the switch unit to switch the bit line.

9. The semiconductor memory device according to claim 1, further comprising:
a leveling unit configured to perform wear leveling in a unit of a page.

10. The semiconductor memory device according to claim 9, wherein
the leveling unit estimates a number of write cycles of the bit line based on the write time, and performs wear leveling based on the number of write cycles.

11. The semiconductor memory device according to claim 1, further comprising:
an external output unit configured to externally output the write time of the bit line.

12. A memory management method comprising:
measuring a write time of a bit line configured to write data.

13. An electronic apparatus comprising:
a semiconductor memory device including a bit line configured to write data; and
a time measurement unit configured to measure a write time of a bit line.
